(19) United States
(12) Patent Application Publication
(10) Pub. No.: US 2021/0083137 A1
(43) Pub. Date: Mar. 18, 2021

(54) Optoelectronic Sensor and Manufacturing Method Thereof, and Optoelectronic Device and Manufacturing Method Thereof

(71) Applicant: BOE TECHNOLOGY GROUP CO., LTD., Beijing (CN)

(72) Inventors: Ling WANG, Beijing (CN); Yicheng LIN, Beijing (CN); Cuili GAI, Beijing (CN); Pan XU, Beijing (CN); Guoying WANG, Beijing (CN)

(21) Appl. No.: 16/633,372

(22) PCT Filed: Jul. 23, 2019
(86) PCT No.: PCT/CN2019/097271

§ 371 Date: Jan. 23, 2020

(30) Foreign Application Priority Data
Jul. 25, 2018 (CN) 201810828403.3

(51) Int. Cl. H01L 31/103; H01L 31/0224; H01L 31/18; H01L 27/146

(52) U.S. Cl. CPC H01L 31/1032; H01L 27/14616; H01L 31/1832; H01L 31/022475

(57) ABSTRACT

The present disclosure provides an optoelectronic sensor and a manufacturing method thereof, and an optoelectronic device and a manufacturing method thereof. The optoelectronic sensor includes a first electrode, a first semiconductor layer, a second semiconductor layer and a second electrode arranged in a stack, wherein each of the first semiconductor layer and the second semiconductor layer is a metal oxide semiconductor layer, the first electrode is a transparent electrode and has a work function greater than that of the first semiconductor layer; and the first semiconductor layer has a conductivity smaller than that of the second semiconductor layer, and has a work function greater than that of the second semiconductor layer.

### CROSS-REFERENCE TO RELATED APPLICATION

The present application claims priority from Chinese patent application No. 201810828403.3 filed on Jul. 25, 2018, the entirety of which is incorporated herein by reference.

### TECHNICAL FIELD

The present disclosure relates to an optoelectronic sensor and a manufacturing method thereof, and an optoelectronic device and a manufacturing method thereof.

### BACKGROUND

An optoelectronic sensing assembly is combined of an optoelectronic sensor and a thin film transistor, wherein the optoelectronic sensor is used for converting an optical signal into an electric signal, and the thin film transistor is used for controlling transmission of the electric signal generated by the optoelectronic sensor.

Conventional thin film transistors are classified into Amorphous Silicon (a-Si) thin film transistors, oxide thin film transistors, and the like based on differences in the semiconductor materials, in which the oxide thin film transistors are more widely used than the a-Si thin film transistors due to advantages such as a lower leakage current and a larger signal-to-noise ratio. Conventional optoelectronic sensors are mainly made of an a-Si semiconductor material, for example, a PN-type photodiode based on a-Si, a positive-intrinsic-negative (PIN) type photodiode based on a-Si, or the like.

### SUMMARY

The present disclosure provides an optoelectronic sensor, including a first electrode, a first semiconductor layer, a second semiconductor layer and a second electrode arranged in a stack, where each of the first semiconductor layer and the second semiconductor layer is a metal oxide semiconductor layer; the first electrode is a transparent electrode and has a work function greater than that of the first semiconductor layer; and the first semiconductor layer has a conductivity smaller than that of the second semiconductor layer, and has a work function greater than that of the second semiconductor layer.

In an embodiment, a width of a first depletion region formed by the first semiconductor layer and the first electrode is proportional to a first Fermi level difference, and the width of the first depletion region is inversely proportional to an oxygen vacancy doping concentration of the first semiconductor layer, the first Fermi level difference being equal to a difference between a Fermi level of the first semiconductor layer and a Fermi level of the first electrode.

In an embodiment, a width of a second depletion region formed by the first semiconductor layer and the second semiconductor layer is proportional to a second Fermi level difference, and the width of the second depletion region is inversely proportional to an oxygen vacancy doping concentration in the first semiconductor layer, the second Fermi level difference being equal to a difference between a Fermi level of the first semiconductor layer and a Fermi level of the second semiconductor layer.

In an embodiment, the first semiconductor layer has an oxygen vacancy doping concentration smaller than that of the second semiconductor layer.

In an embodiment, the first electrode is applied with a negative potential, and the second electrode is applied with a zero potential.

In an embodiment, the first electrode is a metal oxide electrode.

In an embodiment, each of the first semiconductor layer and the second semiconductor layer is an indium gallium zinc oxide semiconductor layer.

In an embodiment, each of the first semiconductor layer and the second semiconductor layer has a thickness ranging from 40 nm to 200 nm.

The present disclosure further provides an optoelectronic device, including: a thin film transistor, and the optoelectronic sensor as described above, where the second electrode of the optoelectronic sensor is electrically coupled to a source or a drain of the thin film transistor.

In an embodiment, the thin film transistor is an oxide thin film transistor.

The present disclosure further provides a manufacturing method for an optoelectronic sensor, including: forming a first electrode; forming a first semiconductor layer on a surface of the first electrode, where the first electrode has a work function greater than that of the first semiconductor layer; forming a second semiconductor layer on a surface of the first semiconductor layer away from the first electrode, where each of the first semiconductor layer and the second semiconductor layer is a metal oxide semiconductor layer, the first semiconductor layer has a conductivity smaller than that of the second semiconductor layer, and has a work function greater than that of the second semiconductor layer; and forming a second electrode on a surface of the second semiconductor layer away from the first semiconductor layer.

In an embodiment, forming the first semiconductor layer on a surface of the first electrode includes: forming the first semiconductor layer on the surface of the first electrode in an environment where argon and oxygen are provided and amount ratio of argon to oxygen is 30:20 to 40:10.

In an embodiment, forming the second semiconductor layer on the surface of the first semiconductor layer away from the first electrode includes: forming the second semiconductor layer on the surface of the first semiconductor layer away from the first electrode in an environment where argon and oxygen are provided and amount ratio of argon to oxygen is 45:5 to 48:2.

In an embodiment, each of the first semiconductor layer and the second semiconductor layer is an indium gallium zinc oxide semiconductor layer.

The present disclosure further provides a manufacturing method for an optoelectronic device, including: providing a substrate; forming a thin film transistor on a surface of the substrate; forming an optoelectronic sensor on a surface of the thin film transistor away from the substrate, where a second electrode of the optoelectronic sensor is electrically coupled to a source or a drain of the thin film transistor;

where forming the optoelectronic sensor on the surface of the thin film transistor away from the substrate including: forming a first electrode; forming a first semiconductor layer on a surface of the first electrode, the first electrode has a work function greater than that of the first semiconductor layer; forming a second semiconductor layer on a surface of the first semiconductor layer away from the first electrode, where each of the first semiconductor layer and the second semiconductor layer is a metal oxide semiconductor layer, the first semiconductor layer has a conductivity smaller than that of the second semiconductor layer, and has a work function greater than that of the second semiconductor layer; and forming a second electrode on a surface of the second semiconductor layer away from the first semiconductor layer.

### BRIEF DESCRIPTION OF DRAWINGS

FIG. 1 is a schematic structural diagram of an optoelectronic sensor according to an embodiment of the present disclosure;

FIG. 2 is a schematic diagram illustrating energy band structures of various layer structures used in manufacture of an optoelectronic sensor according to an embodiment of the present disclosure;

FIG. 3 is a schematic diagram illustrating energy band structures of various layer structures inside an optoelectronic sensor in a thermal equilibrium state according to an embodiment of the present disclosure;

FIG. 4 is a schematic diagram illustrating energy band structures of various layer structures inside an optoelectronic sensor in a negative bias state according to an embodiment of the present disclosure;

FIG. 5 is a schematic diagram illustrating circuit structures of an optoelectronic sensor and a thin film transistor according to an embodiment of the present disclosure;

FIG. 6 is a flowchart of a manufacturing method for an optoelectronic sensor according to an embodiment of the present disclosure;

FIG. 7 is a flowchart of a manufacturing method for an optoelectronic device according to an embodiment of the present disclosure;

FIG. 8 is a schematic diagram illustrating partial structure of an optoelectronic device according to an embodiment of the present disclosure; and

FIG. 9 is flowchart of another manufacturing method for an optoelectronic device according to an embodiment of the present disclosure.

### DETAILED DESCRIPTION

To improve understanding of the above objects, features and advantages, the present disclosure will now be described in detail with the help of accompanying drawings and specific embodiments.

In the description of the present disclosure, “a plurality of” means two or more unless otherwise specified; orientation or position relationships referred by terms “upper”, “lower”, “left”, “right”, “inside”, “outside” and the like are based on the orientation or position relationships shown in the drawings, and are merely for facilitating description of the disclosure and simplifying the description, instead of indicting or implying that the device or component referred to must have a specific orientation or must be configured or operated at a specific orientation, and thus cannot be interpreted as limitations to the present disclosure.

As used herein, it should be noted that terms “install”, “connected to”, and “connect” are to be understood broadly, and may refer to, for example, a fixed connection or a removable connection or an integral connection; or may refer to a mechanical connection or an electrical connection; or may refer to a direct connection, or an indirect connection via an intermedium. Those ordinary skilled in the art may understand the specific meanings of the above terms in the present disclosure according to the specific context.

In the related art, when an a-Si based optoelectronic sensor and an oxide thin film transistor are used to manufacture an optoelectronic sensing assembly, the oxide thin film transistor is manufactured on a substrate first, and then the a-Si based optoelectronic sensor is manufactured. However, a large amount of acidic media such as hydrogen may be introduced during deposition of an a-Si semiconductor layer in the optoelectronic sensor, and since a channel in the oxide thin film transistor is formed by oxide, the introduced acidic media may corrode the channel and cause a threshold voltage of the thin film transistor to be negatively offset, thereby increasing the leakage current of the oxide thin film transistor, and finally reducing performance of the optoelectronic sensing assembly.

Hereinafter, specific embodiments of the present disclosure will be further described in detail with respect to the accompanying drawings and examples. The following embodiments are intended to illustrate the present disclosure, but are not intended to limit the scope of the present disclosure.

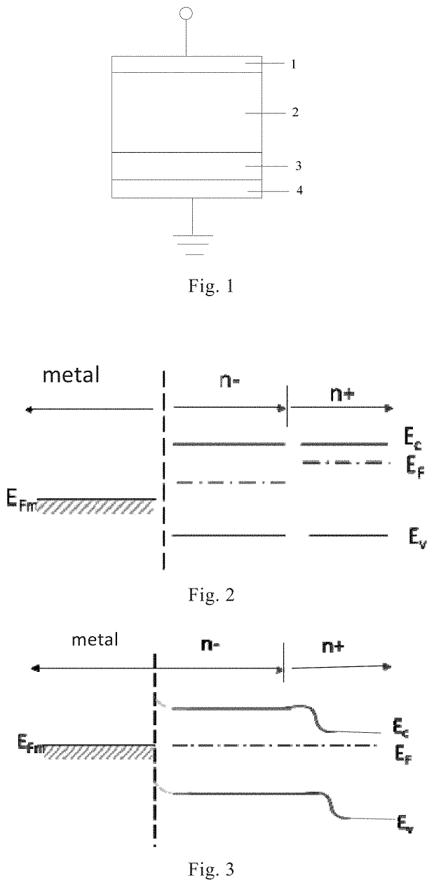

In an embodiment of the present disclosure, there is provided an optoelectronic sensor which, as shown in FIG. 1, may include a first electrode 1, a first semiconductor layer 2, a second semiconductor layer 3 and a second electrode 4 arranged in a stack. Each of the first semiconductor layer 2 and the second semiconductor layer 3 is a metal oxide semiconductor layer; the first electrode 1 is a transparent electrode and has a work function greater than that of the first semiconductor layer 2; and the first semiconductor layer 2 has a conductivity smaller than that of the second semiconductor layer 3, and has a work function greater than that of the second semiconductor layer 3.

Each of the first semiconductor layer 2 and the second semiconductor layer 3 is a metal oxide semiconductor layer and is capable of providing an oxygen vacancy. Since the first semiconductor layer 2 has a conductivity smaller than that of the second semiconductor layer 3, the first semiconductor layer 2 has an oxygen vacancy doping concentration smaller than that of the second semiconductor layer 3.

When light is illuminated on the optoelectronic sensor of the disclosure as described above, the semiconductor layers are excited by the light to generate electrons and holes. Then, the electrons and the holes will move separately under the action of an external electric field to generate a current, thereby realizing photoelectric conversion.

Each of the first semiconductor layer 2 and the second semiconductor layer 3 is a metal oxide semiconductor layer, and various materials may be used for forming the metal oxide semiconductor layers, such as SnO₂, ZnO, CdO, and the like, which can be selected according to the actual application.

The first electrode 1 is a transparent electrode having a light transmitting function. The first electrode may be a metal oxide electrode, such as an Indium-Tin-Oxide (ITO) electrode, a ZnO electrode, or other transparent electrodes, depending on the choice of the material used for manufacture. The second electrode may be made of a common metal.

When the first electrode is a transparent metal oxide electrode, the energy band structures of the first electrode, the first semiconductor layer, and the second semiconductor layer are as shown in FIG. 2.

When the first electrode, the first semiconductor layer, and the second semiconductor layer with the energy band structures shown in FIG. 2 are used for manufacturing an optoelectronic sensor, for example, E_{F} represents the Fermi level, Ec and Ev represent positions of a bottom of conduction band and a top of valence band, respectively, the Fermi levels E_{F} of the first electrode, the first semiconductor layer, and the second semiconductor layer are sequentially increased so that the first electrode has a work function greater than that of the first semiconductor layer, and the first electrode and the first semiconductor layer form a deplete metal-semiconductor contact. Therefore, the first semiconductor layer has a lower electron concentration. Meanwhile, the first semiconductor layer and the second semiconductor layer form a PN-junction-like contact. Since the first semiconductor layer has a lower electron concentration, a PN-junction depletion region of the PN-junction-like contact is mainly formed in the first semiconductor layer so that the depletion region in the first semiconductor layer is wide. When the first electrode is applied with a negative potential and the second electrode is applied with a zero potential, the depletion region of the metal-semiconductor contact is further widened. As a result, the first semiconductor layer is completely occupied by the depletion region inside, and the electron concentration in the first semiconductor layer is very low. Therefore, the recombination probability of electrons and holes excited by illumination in the first semiconductor layer is relatively low, and the electrons and the holes are rapidly separated and converted into a current under the action of the electric field so that the optoelectronic sensor has a high photoelectric conversion rate and high sensitivity. The energy band structures of the optoelectronic sensor manufactured by the above layer structures in a thermal equilibrium state are as shown in FIG. 3, where the Fermi levels of the first electrode, the first semiconductor layer and the second semiconductor layer tend to be the same, and the positions of the bottom of conduction band and the top of valence band of the first semiconductor layer and the second semiconductor layer move downwards.

When the electron concentrations in the first electrode and the second semiconductor layer are much higher than that in the first semiconductor layer, the contact between the first electrode and the first semiconductor layer is similar to an abrupt junction, the contact between the second semiconductor layer and the first semiconductor layer is also similar to an abrupt junction, and the contact between the second electrode and the second semiconductor layer is also similar to an abrupt junction, then a region width of a first space charge region, i.e., the first depletion region, and a region width of a second space charge region, i.e., the second depletion region, may be expressed as:

$$\begin{matrix}{W}_{D} = \sqrt{\frac{2 {ɛ}_{s}}{{qN}_{D}} ( {ψ}_{bi} - V - \frac{kT}{q} )} & ( 1 ) \\ {ψ}_{bi} = \frac{{E}_{F \_ n -} - {E}_{Fm} ( or {E}_{F \_ n +} )}{q} & ( 2 )\end{matrix}$$

where εₛ is a relative dielectric coefficient, N_{D} is the oxygen vacancy doping concentration of the first semiconductor layer, E_{F_n}. is the Fermi level of the first semiconductor layer, E_{Fm} is the Fermi level of the first electrode, E_{F_n}. is the Fermi level of the second semiconductor layer, V is a voltage applied to the optoelectronic semiconductor, q is the cell charge, and k is the Boltzmann constant.

As can be seen from the above equations, the width of a first depletion region formed by the first semiconductor layer and the first electrode is proportional to a first Fermi level difference, and the width of the first depletion region is inversely proportional to the oxygen vacancy doping concentration of the first semiconductor layer, where the first Fermi level difference is equal to a difference between the Fermi level of the first semiconductor layer and the Fermi level of the first electrode.

The width of the second depletion region formed by the first semiconductor layer and the second semiconductor layer is proportional to a second Fermi level difference, and the width of the second depletion region is inversely proportional to the oxygen vacancy doping concentration in the first semiconductor layer, where the second Fermi level difference is equal to a difference between the Fermi level of the first semiconductor layer and the Fermi level of the second semiconductor layer.

As can be seen from the above equations and data relationships, the lower the oxygen vacancy doping concentration in the first semiconductor layer, the wider the depletion region. Therefore, the first semiconductor layer in the present application is controlled to have a low oxygen vacancy doping concentration to increase the width of the depletion region.

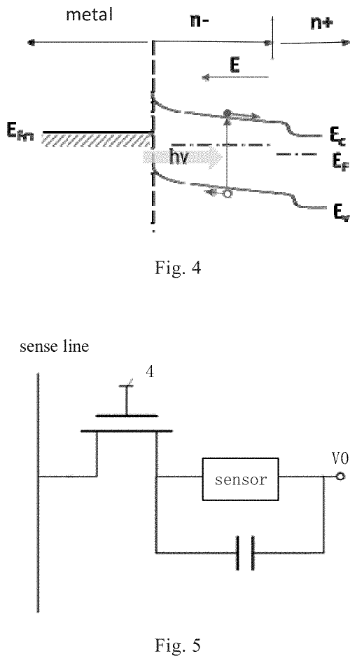

Typically, the second electrode of the optoelectronic sensor is grounded, then the voltage on the second electrode of the optoelectronic sensor is zero volts. When the first electrode is applied with a negative voltage, the optoelectronic sensor is in a negative bias state, and then the energy band structures of the respective layer structures in the optoelectronic sensor are as shown in FIG. 4, where the Fermi levels E_{F} of the first electrode, the first semiconductor layer and the second semiconductor layer decrease in sequence, and the positions of the bottom of conduction band and the top of valence band of the first semiconductor layer and the second semiconductor layer move downwards. As can be seen from the energy band diagram shown in FIG. 4, after the first electrode is applied with the negative voltage, the width of the first depletion region between the first semiconductor layer and the first electrode is further widened, and at the same time, the width of the second depletion region between the first semiconductor layer and the second semiconductor layer is further widened. Then, the width of the depletion regions is close to the thickness of the first semiconductor layer, and the first semiconductor layer is almost fully occupied by the depletion regions, resulting in a very low electron concentration.

When light is illuminated on an optoelectronic sensor with the structures and performance as described above, the respective semiconductor layers are excited by the light to generate electrons and holes. Since the first semiconductor layer is almost fully occupied by the depletion regions, both the concentrations of electrons and holes in the first semiconductor layer are very low. Therefore, the recombination rate of the photogenerated electrons and holes in the first semiconductor layer is relatively low, and the electrons and the holes will be rapidly separated under the action of an external electric field and converted into a photocurrent, which has the advantages of less loss of photogenerated carriers, high photoelectric conversion efficiency and the like, and remarkably increases sensitivity of the optoelectronic sensor. Since the original electron concentration in the second semiconductor layer is relatively high, the electrons and the holes generated in the second semiconductor layer under the excitation of light will be quickly recombined. As a result, the electrons and the holes have a short life, and cannot generate effective photocurrent.

In the present disclosure, each of the first semiconductor layer 2 and the second semiconductor layer 3 is a metal oxide semiconductor layer, and since the first semiconductor layer and the second semiconductor layer have the functions as described above, the type of the metal oxide semiconductor layer may be set according to actual applications. For example, each of the first semiconductor layer and the second semiconductor layer may be an Indium Gallium Zinc Oxide (IGZO) semiconductor layer, and the first semiconductor layer 2, i.e., the first IGZO semiconductor layer, has an oxygen vacancy doping concentration smaller than that of the second semiconductor layer 3, i.e., the second IGZO semiconductor layer.

Based on the positional and functional arrangements of the first semiconductor layer 2 and the second semiconductor layer 3 in the optoelectronic sensor, the thicknesses of the first semiconductor layer 2 and the second semiconductor layer 3 may be set according to actual applications. For example, each of the first semiconductor layer 2 and the second semiconductor layer 3 may have a thickness ranging from 40 nm to 200 nm.

In an embodiment of the present disclosure, there is further provided an optoelectronic device, which may include a thin film transistor (TFT) and the optoelectronic sensor according to the above embodiments of the present disclosure.

There may be many kinds of optoelectronic devices including an optoelectronic sensor and a thin film transistor, and different optoelectronic devices may have different functions. For example, an assembly composed of an optoelectronic sensor and a thin film transistor may have a brightness detection function for detecting brightness of a panel. In this case, the optoelectronic device including the optoelectronic sensor and the thin film transistor may be a brightness detection circuit, a brightness detection device, or the like.

In other embodiments, the optoelectronic sensor and the thin film transistor may be used for fabricating an optical compensation circuit that performs optical compensation to the panel according to the panel brightness information detected by the optoelectronic sensor and the thin film transistor so that the brightness of the panel meets preset requirements. In this case, the optoelectronic device including the optoelectronic sensor and the thin film transistor may be an optical compensation circuit, an optical compensation device, or the like.

As shown in FIG. 5, the second electrode 4 of the optoelectronic sensor is electrically coupled to a source or a drain of the thin film transistor. During operation of the optoelectronic sensor, the first electrode, i.e., VO, is applied with a negative voltage to keep the optoelectronic sensor in a reverse bias state so that the optoelectronic sensor has a small current in a dark state, and an initial charge quantity Q is stored in a capacitor coupled in parallel with the optoelectronic sensor. After being illuminated by light, the optoelectronic sensor is in operation while the TFT is turned off. Accordingly, the current generated in the optoelectronic sensor is increased, and the charge quantity in the capacitor is changed. After a period of time, the charge quantity in the capacitor is changed by ΔQ, and operation of the optoelectronic sensor is finished, a positive voltage is applied to a gate of the TFT and the TFT is turned on. Then, charges in the capacitor is input to an external circuit through a sense line, and illumination information can be obtained by amplifying the charges. Further, an IC circuit may perform optical compensation on the panel according to the amplified charges so that the brightness of the panel meets preset requirements.

Since the optoelectronic sensor provided by the present disclosure has an photoelectric conversion function, and has the advantages of high photoelectric conversion efficiency, high sensitivity, and the like, the optoelectronic device formed by the optoelectronic sensor and the TFT also has the advantages of the optoelectronic sensor.

Since the semiconductor layers in the optoelectronic sensor of the present disclosure are made of oxide, introduction of H atoms is avoided during the manufacture process, and oxide channel of the TFT is prevented from being damaged, thereby ensuring structural stability and performance stability of the TFT, and thus ensuring structural stability and performance stability of the optoelectronic device formed by the optoelectronic sensor and the TFT.

In the optoelectronic device provided by the present disclosure, the second electrode of the optoelectronic sensor and a third electrode (source or drain) of the TFT may be made of a same material, and the second electrode and the third electrode may be manufactured through a single mask process, thereby simplifying the manufacture process of the optoelectronic device and improving the manufacture efficiency.

In other embodiments, the second electrode of the optoelectronic sensor and the third electrode of the TFT may be manufactured by different mask processes. The metal oxide semiconductor layers of the optoelectronic sensor and an active layer of the TFT may be manufactured by different mask processes.

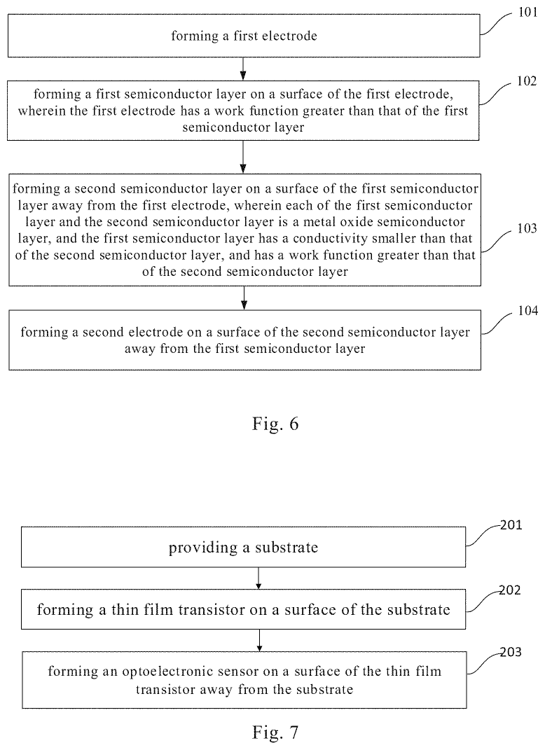

In an embodiment of the present disclosure, there is further provided a manufacturing method for the optoelectronic sensor as described above. As shown in FIG. 6, in the embodiment of the present disclosure, the manufacturing method for the optoelectronic sensor according to the above embodiments of the present disclosure includes the following steps 101 to 104.

At step 101, a first electrode is formed.

During manufacture of the optoelectronic sensor, a substrate may be selected first, and then the first electrode is t formed on the substrate.

Since the first electrode is a transparent electrode having a conductive function, the first electrode is typically a metal oxide electrode, such as an ITO electrode, an IZO electrode, and the like.

The first electrode may be formed by various processes. For example, the first electrode may be formed on the substrate by sputtering or the like, and the formation process of the first electrode may be set according to actual applications.

At step 102, a first semiconductor layer is formed on the first electrode, where the first electrode has a work function greater than that of the first semiconductor layer.

After forming the first electrode on the substrate, the first semiconductor layer is formed on the first electrode.

The formation process of the first semiconductor layer may be set according to actual applications. For example, when the first semiconductor layer is a metal oxide semiconductor layer, the metal oxide semiconductor may be used as a target material to form the metal oxide semiconductor layer on the first electrode by sputtering. For example, solid IGZO may be used as the target material to form an IGZO layer as the first semiconductor layer on the first electrode by sputtering.

At step 103, a second semiconductor layer is formed on the first semiconductor layer, where each of the first semiconductor layer and the second semiconductor layer is a metal oxide semiconductor layer, and the first semiconductor layer has a conductivity smaller than that of the second semiconductor layer.

After forming the first semiconductor layer on the first electrode, a second semiconductor layer is formed on the first semiconductor layer. Specifically, the second semiconductor layer is formed on a surface of the first semiconductor layer away from the first electrode.

In the manufacturing method of the present disclosure, both the first semiconductor layer and the second semiconductor layer are made of a metal oxide semiconductor layer, and in order for a better photoelectric conversion function of the optoelectronic sensor, the first semiconductor layer has a conductivity smaller than that of the second semiconductor layer.

Since each of the second semiconductor layer and the first semiconductor layer is made of an oxide semiconductor material, the second semiconductor layer may be made through a same process as that of the first semiconductor layer, for example, through a process such as sputtering.

At step 104, a second electrode is formed on the second semiconductor layer.

After forming the second semiconductor layer on the first semiconductor layer, the second electrode is formed on the second semiconductor layer.

The second electrode has a conductive function and may be an electrode made of a common metal or other material.

The optoelectronic sensor manufactured by the manufacturing method provided by the embodiments of the disclosure has the advantages of a high photoelectric conversion efficiency, high sensitivity and the like, and this manufacturing method has the advantages of simple process, low cost and the like.

In an embodiment of the present disclosure, the steps of forming the first semiconductor layer on the first electrode and forming the second semiconductor layer on the first semiconductor layer may further include: in an environment where argon and oxygen are provided, by controlling amount ratio of argon and oxygen, the first semiconductor layer is formed on the surface of the first electrode, and the second semiconductor layer is formed on the surface of the first semiconductor layer away from the first electrode.

The amount ratio of argon and oxygen may be set according to a variety of factors such as types of materials used to form the semiconductor layers, and desired performance of the optoelectronic sensor. For example, in a case where each of the first semiconductor layer and the second semiconductor layer is the IGZO semiconductor layer, the first semiconductor layer is formed on the surface of the first electrode in an environment where argon and oxygen are provided and the amount ratio of argon and oxygen is controlled to be 30:20 to 40:10; and the second semiconductor layer is formed on the surface of the first semiconductor layer away from the first electrode by controlling the amount ratio of argon and oxygen to be 45:5 to 48:2. In an example, the first semiconductor layer is formed on the surface the first electrode by controlling the amount ratio of argon and oxygen to be 40:10; and the second semiconductor layer is formed on the surface of the first semiconductor layer away from the first electrode by controlling the amount ratio of argon and oxygen to be 48:2. The amount ratio of argon and oxygen may be set according to actual requirements.

In an embodiment of the present disclosure, there is further provided a manufacturing method for the optoelectronic device provided in the above embodiments of the present disclosure. FIG. 7 is a flowchart of a manufacturing method for an optoelectronic device according to an embodiment of the present disclosure, the manufacturing method includes the following steps 201 to 203.

At step 201, a substrate is provided.

At step 202, a thin film transistor is formed on the substrate.

At step 203, an optoelectronic sensor is formed on a side of the thin film transistor away from the substrate. A second electrode of the optoelectronic sensor is electrically coupled to a source or a drain of the thin film transistor.

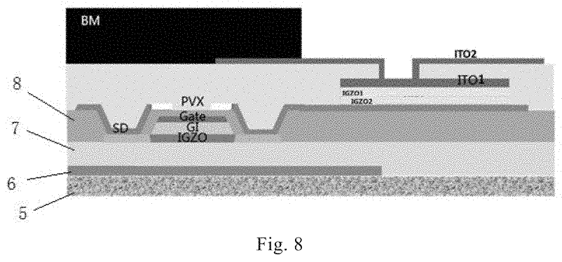

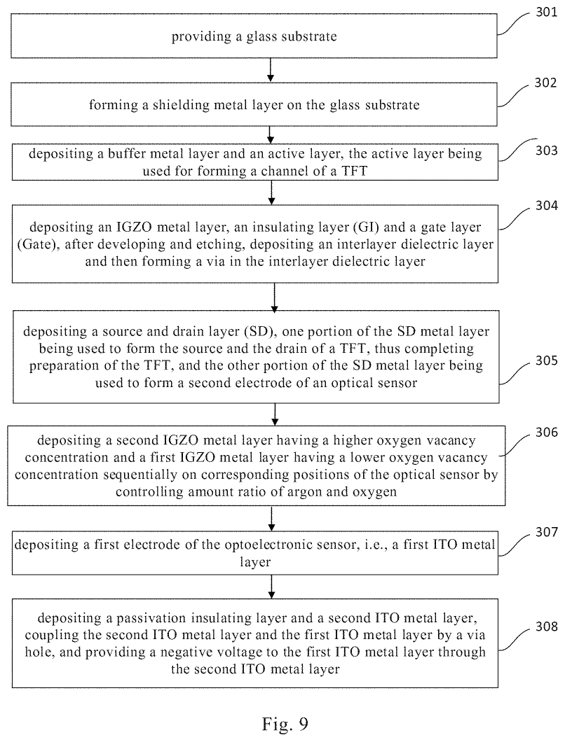

FIG. 8 is a schematic diagram illustrating partial structure of an optoelectronic device according to an embodiment of the present disclosure, and FIG. 9 is another flowchart of a manufacturing method for an optoelectronic device according to an embodiment of the present disclosure. The manufacturing method for the optoelectronic device will be explained in detail below with reference to FIGS. 8 and 9. The manufacturing method for the optoelectronic device provided in the embodiment of the present disclosure includes the following steps 301 to 308.

At step 301, a glass substrate 5 is provided.

At step 302, a shielding metal layer 6 is formed on the glass substrate for shielding ambient light.

At step 303, a buffer metal layer 7 and an active layer are deposited, the active layer being used for forming a channel of a TFT.

At step 304, an IGZO metal layer (IGZO), an insulating layer (GI) and a gate layer (Gate) are deposited sequentially, and after etching and developing, an interlayer dielectric layer 8 having an insulating function is deposited, and then, a connect via (CNT) is formed in the interlayer dielectric layer.

At step 305, a source and drain layer (SD) is deposited, one portion of the SD metal layer being used to form the source and the drain of the TFT, thus completing manufacture of the TFT, and the other portion of the SD metal layer being used to form a second electrode of an optical sensor.

At step 306, a second IGZO metal layer (IGZO2) having a higher oxygen vacancy concentration and a first IGZO metal layer (IGZO1) having a lower oxygen vacancy concentration are sequentially deposited on corresponding positions of the optical sensor by controlling amount ratio of argon and oxygen.

At step 307, a first electrode of the optoelectronic sensor, i.e., a first ITO metal layer (ITO1) is deposited.

At step 308, a passivation insulating layer (PVX) and a second ITO metal layer (ITO2) are sequentially deposited, the second ITO metal layer (ITO2) and the first ITO metal layer (ITO1) are connected through a via hole, and a negative voltage is provided to the first ITO metal layer (ITO1) through the second ITO metal layer (ITO2).

The present disclosure provides a novel optoelectronic sensor, optoelectronic device, and manufacturing methods thereof. The optoelectronic sensor of the present disclosure includes a first electrode, a first semiconductor layer, a second semiconductor layer and a second electrode arranged in a stack, wherein each of the first semiconductor layer and the second semiconductor layer is a metal oxide semiconductor layer, and the first electrode is a transparent electrode. Since the first electrode has a work function greater than that of the first semiconductor layer, and the first semiconductor layer has a conductivity smaller than that of the second semiconductor layer, in a case where the optoelectronic sensor is illuminated by light, the semiconductor layers are excited by the light to generate electrons and holes. Thus, the electrons and the holes will be separated and move under the action of an external electric field to generate a current, thereby realizing photoelectric conversion.

Since the first electrode has a work function greater than that of the first semiconductor layer, and the first semiconductor layer has a conductivity smaller than that of the second semiconductor layer, the electron and hole concentrations inside the first semiconductor layer after light excitation are both relatively low, resulting in a low recombination rate of electrons and holes. Further, the electrons and the holes will be rapidly separated under the action of an external electric field and converted into a photocurrent, so that the optoelectronic sensor has advantages such as a high photoelectric conversion rate and high sensitivity.

During manufacture of the optoelectronic device formed by the optoelectronic sensor and the thin film transistor, acidic media such as H is not introduced when the metal oxide semiconductor layers of the optoelectronic sensor are formed after the thin film transistor is formed on the substrate. As a result, oxide channels of the thin film transistors are prevented from being damaged, thereby ensuring structural stability and performance stability of the thin film transistors, and so that the optoelectronic device formed by the optoelectronic sensor and the thin film transistor has advantages such as stable performance.

The optoelectronic sensor, the optoelectronic device and the manufacturing methods thereof of the present disclosure are described in detail above, and specific examples are applied herein to explain the principles and embodiments of the present disclosure, but the description of the above embodiments is only used to help to understand the methods and the core idea of the present disclosure. At the same time, for those ordinary skilled in the art, there will be changes in the specific embodiments and application scopes based on the ideas of the present disclosure. In conclusion, the content of the description should not be construed as limiting the disclosure.

1. An optoelectronic sensor, comprising a first electrode, a first semiconductor layer, a second semiconductor layer and a second electrode sequentially arranged in a stack, wherein each of the first semiconductor layer and the second semiconductor layer is a metal oxide semiconductor layer;
the first electrode is a transparent electrode and has a work function greater than that of the first semiconductor layer; and
the first semiconductor layer has a conductivity smaller than that of the second semiconductor layer, and has a work function greater than that of the second semiconductor layer.

2. The optoelectronic sensor according to claim 1, wherein a width of a first depletion region formed by the first semiconductor layer and the first electrode is proportional to a first Fermi level difference, and the width of the first depletion region is inversely proportional to an oxygen vacancy doping concentration of the first semiconductor layer, the first Fermi level difference being equal to a difference between a Fermi level of the first semiconductor layer and a Fermi level of the first electrode.

3. The optoelectronic sensor according to claim 1, wherein a width of a second depletion region formed by the first semiconductor layer and the second semiconductor layer is proportional to a second Fermi level difference, and the width of the second depletion region is inversely proportional to an oxygen vacancy doping concentration in the first semiconductor layer, the second Fermi level difference being equal to a difference between a Fermi level of the first semiconductor layer and a Fermi level of the second semiconductor layer.

4. The optoelectronic sensor according to claim 3, wherein the first semiconductor layer has an oxygen vacancy doping concentration smaller than that of the second semiconductor layer.

5. The optoelectronic sensor according to claim 1, wherein the first electrode is coupled to a negative potential, and the second electrode is coupled a zero potential.

6. The optoelectronic sensor according to claim 5, wherein the first electrode is a metal oxide electrode.

7. The optoelectronic sensor according claim 1, wherein each of the first semiconductor layer and the second semiconductor layer is an indium gallium zinc oxide semiconductor layer.

8. The optoelectronic sensor according to claim 1, wherein each of the first semiconductor layer and the second semiconductor layer has a thickness ranging from 40 nm to 200 nm.

9. An optoelectronic device, comprising a thin film transistor, and the optoelectronic sensor according to claim 1, wherein the second electrode of the optoelectronic sensor is electrically coupled to a source or a drain of the thin film transistor.

10. The optoelectronic device according to claim 9, wherein the thin film transistor is an oxide thin film transistor.

11. A manufacturing method for an optoelectronic sensor, comprising:
forming a first electrode;
forming a first semiconductor layer on a surface of the first electrode, wherein the first electrode has a work function greater than that of the first semiconductor layer;
forming a second semiconductor layer on a surface of the first semiconductor layer away from the first electrode, wherein each of the first semiconductor layer and the second semiconductor layer is a metal oxide semiconductor layer, and the first semiconductor layer has a conductivity smaller than that of the second semiconductor layer, and has a work function greater than that of the second semiconductor layer; and
forming a second electrode on a surface of the second semiconductor layer away from the first semiconductor layer.

12. The manufacturing method according to claim 11, wherein forming the first semiconductor layer on a surface of the first electrode comprises:
forming the first semiconductor layer on the surface of the first electrode in an environment where argon and oxygen are provided and amount ratio of argon to oxygen is 30:20 to 40:10.

13. The manufacturing method according to claim 11, wherein forming the second semiconductor layer on the surface of the first semiconductor layer away from the first electrode comprises:
forming the second semiconductor layer on the surface of the first semiconductor layer away from the first electrode in an environment where argon and oxygen are provided and amount ratio of argon to oxygen is 45:5 to 48:2.

14. The manufacturing method according to claim 12, wherein each of the first semiconductor layer and the second semiconductor layer is an indium gallium zinc oxide semiconductor layer.

15. A manufacturing method for an optoelectronic device, comprising:
providing a substrate;
forming a thin film transistor on a surface of the substrate;
forming an optoelectronic sensor on a surface of the thin film transistor away from the substrate, wherein a second electrode of the optoelectronic sensor is electrically coupled to a source or a drain of the thin film transistor;
wherein forming the optoelectronic sensor on the surface of the thin film transistor away from the substrate comprising:
forming a first electrode;
forming a first semiconductor layer on a surface of the first electrode, the first electrode has a work function greater than that of the first semiconductor layer;
forming a second semiconductor layer on a surface of the first semiconductor layer away from the first electrode, each of the first semiconductor layer and the second semiconductor layer is a metal oxide semiconductor layer, and the first semiconductor layer has a conductivity smaller than that of the second semiconductor layer, and has a work function greater than that of the second semiconductor layer; and
forming a second electrode on a surface of the second semiconductor layer away from the first semiconductor layer.

16. The optoelectronic sensor according to claim 2, wherein a width of a second depletion region formed by the first semiconductor layer and the second semiconductor layer is proportional to a second Fermi level difference, and the width of the second depletion region is inversely proportional to an oxygen vacancy doping concentration in the first semiconductor layer, the second Fermi level difference being equal to a difference between a Fermi level of the first semiconductor layer and a Fermi level of the second semiconductor layer.

17. The optoelectronic sensor according to claim 16, wherein the first semiconductor layer has an oxygen vacancy doping concentration smaller than that of the second semiconductor layer.

18. The optoelectronic sensor according to claim 2, wherein the first electrode is coupled to a negative potential, and the second electrode is coupled a zero potential.

19. The optoelectronic sensor according to claim 18, wherein the first electrode is a metal oxide electrode.

20. The optoelectronic sensor according to claim 2, wherein each of the first semiconductor layer and the second semiconductor layer is an indium gallium zinc oxide semiconductor layer.
